(19) United States
(12) Patent Application Publication
(10) Pub. No.: US 2008/0067929 A1
(43) Pub. Date: Mar. 20, 2008

(54) Organic electroluminescent device and fabrication method thereof

(75) Inventor: Chien-Chung Kuo, Taichung County (TW)

Correspondence Address: BIRCH STEWART KOLASCH & BIRCH, PO BOX 747, FALLS CHURCH, VA, 22040-0747, US

(73) Assignee: WINTEK CORPORATION

(21) Appl. No.: 11/522,989

(22) Filed: Sep. 19, 2006

(51) Int. Cl. H01L 51/00

(52) U.S. Cl. 313/506; 313/504

(57) ABSTRACT

An organic electroluminescent structure comprises a support structure and an organic electroluminescent structure with a plurality of subpixels. The support structure comprises a substrate, a signal transmission layer, and a plurality of strip-like protrusions disposed on the substrate. The strip-like protrusion has a first lateral side and a second lateral side, which are opposite to each other and along the axial direction of the strip-like protrusion. A first included angle created by the first lateral side and the substrate is obtuse, and a second included angle created by the second lateral side and the substrate is acute. The organic electroluminescent structure has disconnections separately at the undersides of the second lateral sides of the strip-like protrusions. Therefore, no spacing gap is needed to divide the organic electroluminescent structure into different subpixels in one of the axial directions, and the aperture ratio of the display device is increased.

### FIELD OF THE INVENTION

The present invention relates to an organic electroluminescent display, particularly to a high aperture ratio organic electroluminescent structure and a fabrication method thereof.

### BACKGROUND OF THE INVENTION

Organic electroluminescent displays (OLEDs) can be classified into passive matrix OLED and active matrix OLED. It usually utilizes a current to drive an organic electroluminescent structure to emit light. The organic electroluminescent structure comprises an anode layer, an organic layer and a cathode layer which are laminated in sequence.

The thin films of the organic layer usually adopt a vacuum evaporation process by using shadow mask. To achieve high luminance efficiency, it needs to form such a shadow mask of finely pattern on the substrate when fine pixels and patterns for the OLED are manufactured.

FIG. 1A, FIG. 1B, and FIG. 1C illustrate the cathode patterning process of a conventional organic electroluminescent structure. The substrate 1 has an anode layer 2 and a plurality of cathode separators 3. The anode layer 2 has the pattern of parallel strips and has Y1-Y2 direction spacing gaps 7, which are perpendicular to the cathode separators 3, as shown in FIG. 2. The cathode separators, which have a strip-like structure with an inverted-trapezoid cross-section 3, are formed on the substrate 1 and the anode layer 2. The cathode separators 3 are parallel arranged along X1-X2 direction and can automatically separate the cathode layer. As shown in FIG. 1B, an organic layer 4 is formed on the anode layer 2 and the cathode separators 3 with a vacuum evaporation process. Next, as shown in FIG. 1C, a cathode layer 5 is formed on the organic layer 4 by a vacuum evaporation process and the cathode layer 5 is automatically patterned by the cathode separators 3 at the same time, and the strips of the patterned cathode layer are parallel arranged along X1-X2 direction.

FIG. 2 and FIG. 3 schematically show pixels of a conventional organic electroluminescent structure, wherein P is the length of the pixel 6, T is the width of the cathode separator 3, and V is the width of the spacing gap 7 of the parallel strips of the anode layer 2. When the cathode separator 3 is disposed on the pixel 6 along X1-X2 direction and the spacing gaps 7 of the parallel strips of the anode layer 2 are on the pixel 6 along Y1-Y2 direction, the effective light-emitting area of the pixel 6 is ((P−3V)*(P−T)), and the total area of the pixel 6 is (P*P), and then, the aperture ratio of the pixel 6 is (P−3V)*(P−T)/P*P. When the cathode separators 3 are disposed on the pixel 6 along Y1-Y2 direction and the spacing gap 7 of the parallel strips of the anode layer 2 are disposed on the pixel 6 along X1-X2 direction, the aperture ratio of the pixel 6 is (P−3T)*(P−V)/P*P. Therefore, it can be concluded that decreasing the width of the cathode separators 3 or the width of the spacing gaps 7 of the parallel strips of the anode layer 2 can enhance the aperture ratio.

The conventional technology needs the cathode separators 3 to automatically pattern the cathode layer 5. However, the width of the cathode separator 3 is hard to decrease and then the aperture ratio is hard to enhance. Further, the inverted-trapezoid structure must be fabricated with the expensive chemically-amplified photoresist, and the angles of the inverted trapezoid are hard to control. Therefore, the problems of low yield and high cost in the conventional technology are generated.

Accordingly, the present invention proposes a high aperture ratio organic electroluminescent device and a fabrication method thereof to overcome the abovementioned problems.

### SUMMARY OF THE INVENTION

The primary objective of the present invention is to provide a high aperture ratio organic electroluminescent device to fully perform the characteristic of high brightness of the organic electroluminescent display.

Another objective of the present invention is to provide a fabrication method of an organic electroluminescent device, whereby the fabricated organic electroluminescent display has a high aperture ratio.

The present invention is a high aperture ratio organic electroluminescent device, which comprises a support structure and an organic electroluminescent structure with a plurality of subpixels. The support structure comprises a substrate, a signal transmission layer which is disposed on the substrate, and a plurality of strip-like protrusions which are disposed on the surface of the substrate with the signal transmission layer, wherein the strip-like protrusions are parallel arranged on the substrate, and the strip-like protrusion has a first lateral side and a second lateral side, which are opposite to each other and along the axial direction of the strip-like protrusion. A first included angle created by the first lateral side and the substrate is an obtuse angle, and a second included angle created by the second lateral side and the substrate is an acute angle. The organic electroluminescent structure is formed on the signal transmission layer extending the first lateral side of the strip-like protrusions but has disconnections separately at the undersides of the second lateral sides of the strip-like protrusions.

### BRIEF DESCRIPTION OF HE DRAWINGS

FIG. 1A is a schematic diagram of step 1 of the cathode patterning process of a conventional organic electroluminescent structure.

FIG. 1B is a schematic diagram of step 2 of the cathode patterning process of a conventional organic electroluminescent structure.

FIG. 1C is a schematic diagram of step 3 of the cathode patterning process of a conventional organic electroluminescent structure.

FIG. 2 is a diagram schematically showing pixels of a conventional organic electroluminescent structure.

FIG. 3 is a diagram schematically showing pixels of another conventional organic electroluminescent structure.

FIG. 4 is a diagram schematically showing the structure of the strip-like protrusions of the present invention.

FIG. 5A and FIG. 5B are diagrams schematically showing that the present invention's strip-like protrusions of a negative-type photoresist are fabricated with an oblique exposure process.

FIG. 6A and FIG. 6B are diagrams schematically showing that the present invention's strip-like protrusions of a positive-type photoresist are fabricated with an oblique exposure process.

FIG. 7A to FIG. 7D are diagrams schematically showing that the strip-like protrusions of the present invention are fabricated with an oblique etching process.

FIG. 8A is a top view of the pixels in a first embodiment of the present invention.

FIG. 8B is a section view along line 8B-8B in FIG. 8A.

FIG. 9A is a top view of the pixels in a second embodiment of the present invention.

FIG. 9B is a section view along line 9B-9B in FIG. 9A.

FIG. 10 is a diagram schematically showing the present invention's structure applied to an active matrix OLED.

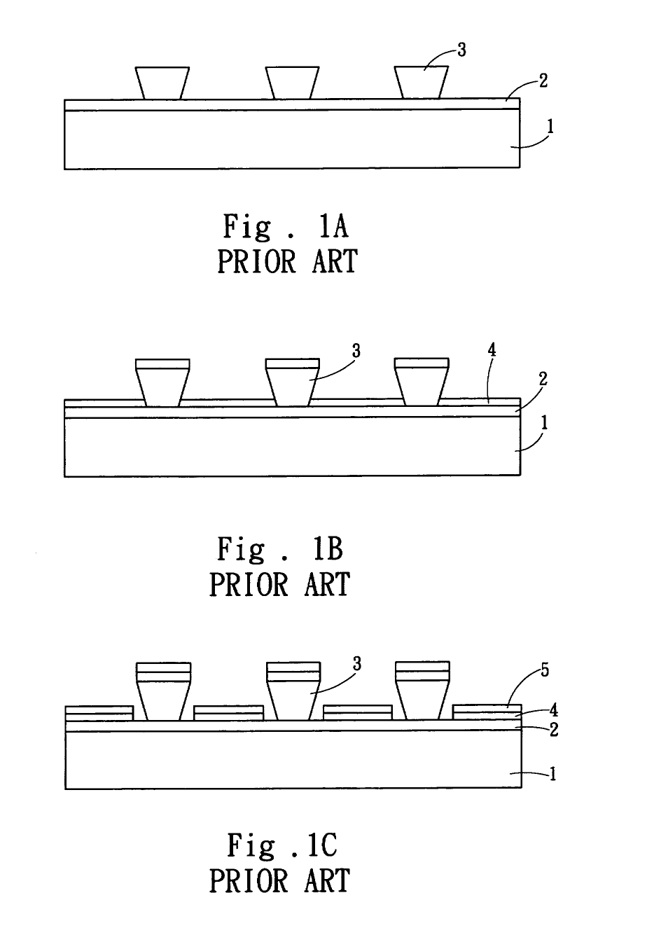

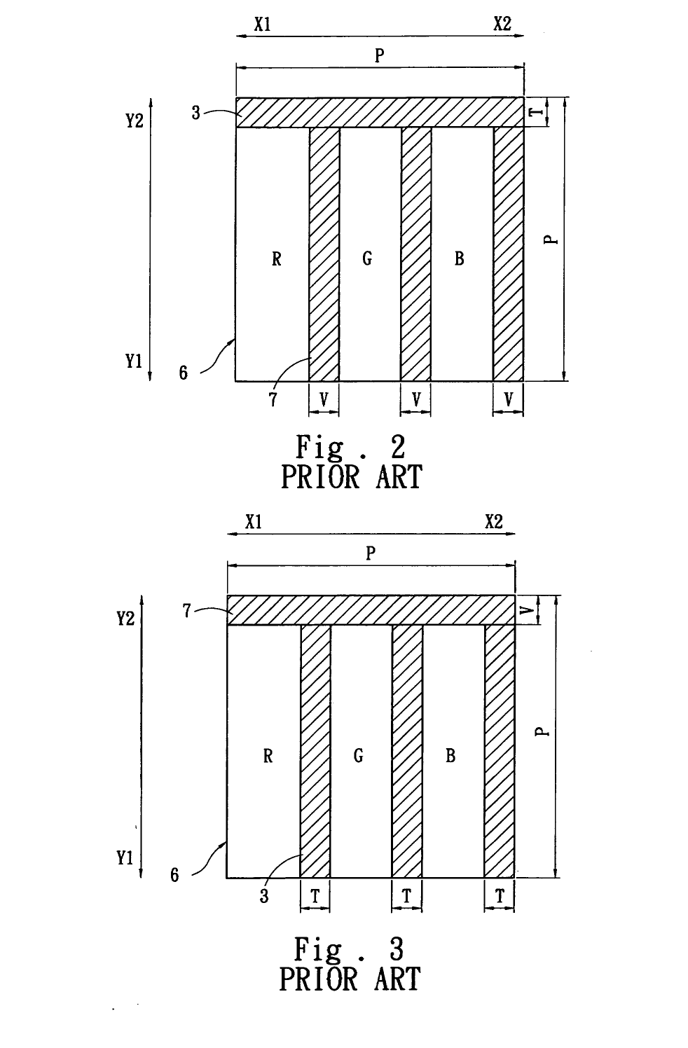

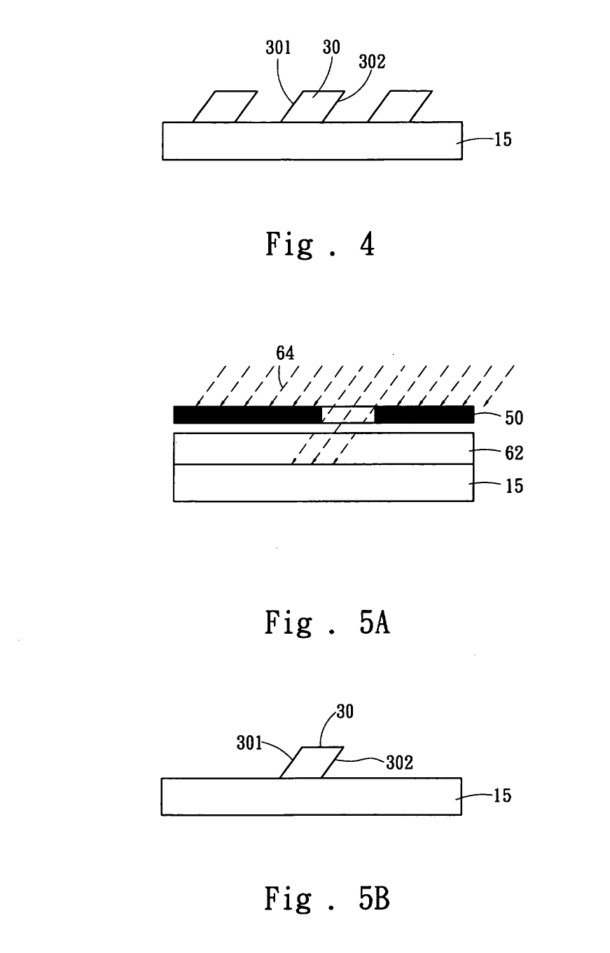

### DETAILED DESCRIPTION OF THE PREFERRED EMBODIMENTS

To enable the objectives, characteristics, and efficacies of the present invention to be more easily understood, the preferred embodiments of the present invention are described below in cooperation with the drawings.

FIG. 4 is a diagram schematically showing the structure of the strip-like protrusions of the present invention. The strip-like protrusion 30 of the present invention is disposed on a substrate 15 and has a first lateral side 301 and a second lateral side 302, which are opposite to each other and along the axial direction of the strip-like protrusion 30. A first included angle created by the first lateral side 301 and the substrate 15 is an obtuse angle, and a second included angle created by the second lateral side 302 and the substrate 15 is an acute angle.

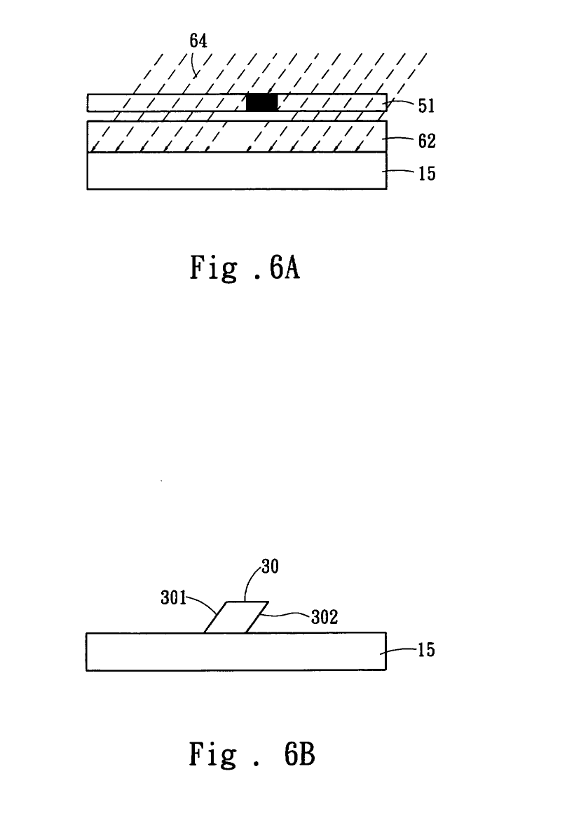

If the strip-like protrusions 30 are of an organic photosensitive material, they can be fabricated with an oblique exposure process, which includes forming the organic photosensitive material, pre-baking, oblique exposing, developing, post-baking, etc. The organic photosensitive material may be a negative-type photoresist or a positive-type photoresist. Refer to FIG. 5A and FIG. 5B for a diagram schematically showing the fabrication process of the strip-like protrusions of a negative-type photoresist according to the present invention. First, an organic photosensitive material 62 (the material of the strip-like protrusion 30) is coated on the substrate 15 and pre-baked at an appropriate temperature to get a slight curing. Second, an exposure step is performed on the pre-baked organic photosensitive material 62 with an oblique exposure light 64 and a photomask 50 having the pattern of parallel strips. Third, the organic photosensitive material 62 is developed and post-baked to form the strip-like protrusions 30 having the first lateral sides 301 and the second lateral sides 302. Refer to FIG. 6A and FIG. 6B for a diagram schematically showing the fabrication process of the strip-like protrusions of a positive-type photoresist according to the present invention. The fabrication process of the strip-like protrusions of a positive-type photoresist is similar to that of the negative-type photoresist, but the opaque region of the photomask 51 used herein is complementary to that of the photomask 50.

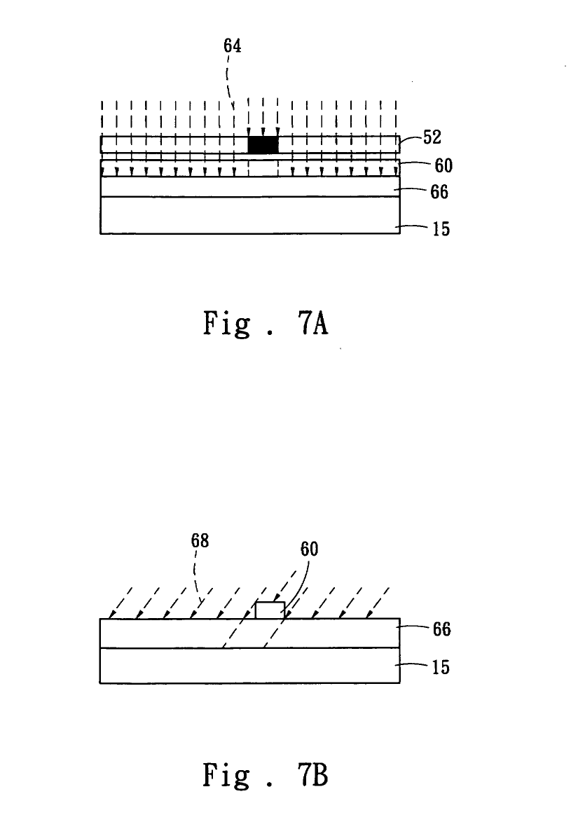

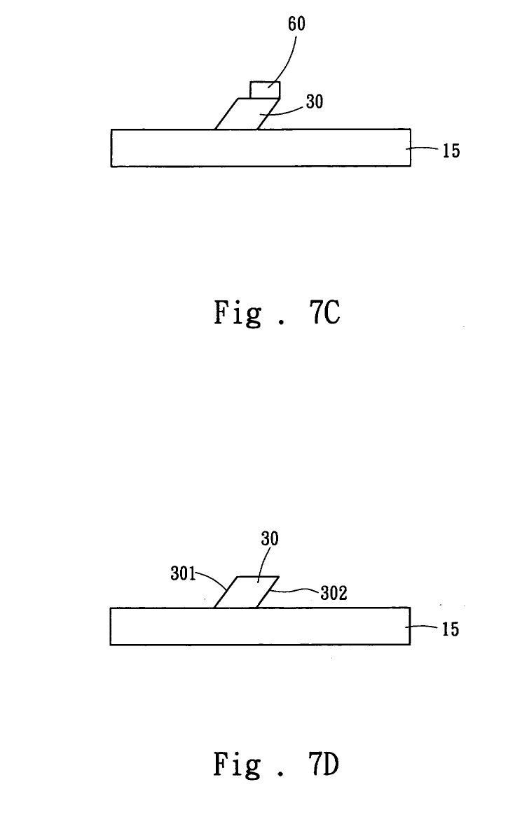

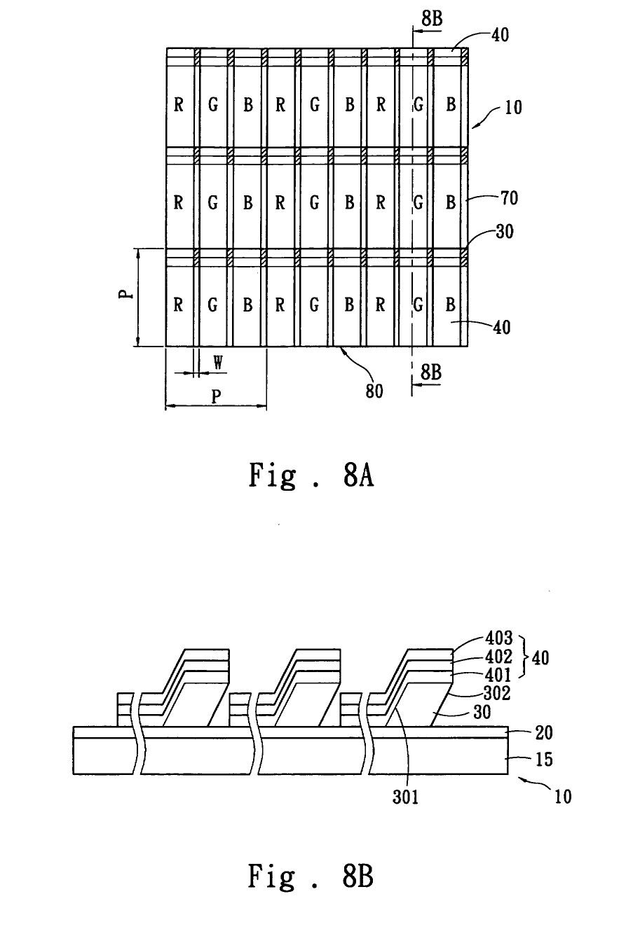

If the strip-like protrusions 30 are of an inorganic material, they can be fabricated with an oblique etching process, which includes depositing an inorganic film, coating a photoresist, pre-baking, exposing, developing, post-baking, oblique dry etching of the inorganic material, stripping the photoresist, etc. Refer to FIG. 7A to FIG. 7D. Firstly, an inorganic material 66 (the material of the strip-like protrusion 30) is deposited on the substrate 15. Second, a photoresist 60 is coated over the inorganic material 66 and pre-baked at an appropriate temperature to slight solidify. Second, an exposure step is performed on the pre-baked photoresist 60 with an exposure light 64 and a photomask 52 having the pattern of parallel strips. Third, the exposed photoresist 60 is developed and post-baked to form a protective photoresist 60 of a parallel strip-like pattern. Fourth, an oblique etching process is performed on the inorganic material 66 with an etching gas 68. Finally, the photoresist 60 is stripped to form the strip-like protrusions 30 having the first lateral sides 301 and the second lateral sides 302.

Refer to FIG. 8A and FIG. 8B for showing a first embodiment of the high aperture ratio organic electroluminescent device of the present invention. It is a passive matrix OLED and comprises a support structure 10 and an organic electroluminescent structure 40 with a plurality of subpixels. The support structure 10 comprises a substrate 15, a signal transmission layer 20 which is disposed on the substrate 15 and has the pattern of parallel strips to be used to conduct electrical signals, and a plurality of strip-like protrusions 30 which are disposed on the surface of the substrate 15 and the signal transmission layer 20 with the axial direction thereof vertical to that of the signal transmission layer 20.

The organic electroluminescent structure 40 comprises a first electrode layer 401, an organic layer 402 and a second electrode layer 403. The organic electroluminescent structure 40 is formed on the signal-transmission-layer-containing side of the support structure 10 and extends from the substrate 15 and the signal transmission layer 20 to the first lateral sides 301 of the strip-like protrusions 30 and then has disconnections at the undersides of the second lateral sides 302. The first electrode layer 401 of the organic electroluminescent structure 40 has the pattern of parallel strips. As shown in FIG. 8A, the first electrode layer 401 forms a plurality of independent regions for disposing R, G, B subpixels via the second lateral sides 302 of the strip-like protrusions 30 and a plurality of subpixel spacing gaps 70, which are parallel arranged and vertical to the axial direction of the strip-like protrusions 30.

In the organic electroluminescent structure 40 of the first embodiment, as R, Q, B subpixels are perpendicular to the axial direction of the strip-like protrusions 30 and disconnect at the undersides of the second lateral sides 302. No spacing gap is needed to prevent electrical connections in that direction. Therefore, the area where no light is emitted is reduced, and the aperture ratio is increased.

In the first embodiment, as the length of the pixel 80 is P, the width of the subpixel spacing gap 70 is W, a pixel 80 has three subpixels R, G, B, functioning as the displaying elements of the organic electroluminescent structure 40, the aperture ratio is (P−

3W)* P/P*P.

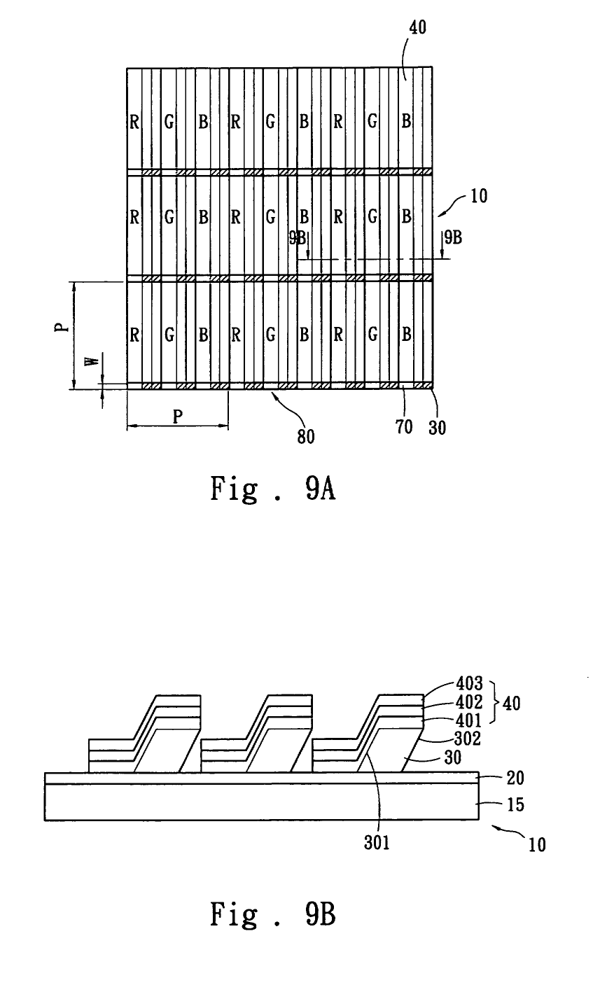

Refer to FIG. 9A and FIG. 9B for showing a second embodiment of the high aperture ratio organic electroluminescent device of the present invention. The structure of this embodiment is similar to that of the first embodiment and comprises an organic electroluminescent structure 40 and a support structure 10. The support structure 10 comprises a substrate 15, a signal transmission layer 20 and a plurality of strip-like protrusions 30. The difference between the first and the second embodiments is the disposing direction of the strip-like protrusions 30 on the pixels 80.

In the second embodiment, as the subpixels of the organic electroluminescent structure 40 are parallel to the axial direction of the strip-like protrusions 30. As the subpixels disconnect at the undersides of the second lateral sides 302 of the strip-like protrusions 30, no spacing gap is needed to prevent electrical connections in that direction. Therefore, the area where no light is emitted is reduced, and the aperture ratio is enhanced.

In the second embodiment, as the length of the pixel 80 is P, the width of the subpixel spacing gap 70 is W, and a pixel 80 has three subpixels R, G, B functioning as the displaying elements of the organic electroluminescent structure 40, the aperture ratio will be (P−W)*P/P*P. The aperture ratio of the second embodiment is higher than that of the first embodiment.

When the abovementioned two embodiments are applied to a bottom emission OLED, the substrate 15, the first electrode layer 401 and the strip-like protrusions 30 are made of a transparent material. The signal transmission layer 20 can be made of a transparent material or reduce its strip width. When the abovementioned two embodiments are applied to a top emission OLED, the second electrode layer 402 can be made of a transparent material. When the abovementioned two embodiments are applied to a double emission OLED, the substrate 15, the first electrode layer 401, the second electrode layer 402 and the strip-like protrusions 30 can be made of a transparent material. Similarly, the signal transmission layer 20 can be made of a transparent material or reduce its strip width.

The method of fabricating the organic electroluminescent device described in the abovementioned two embodiments comprises forming a signal transmission layer 20 on a substrate 15 for electrical conduction, forming a plurality of strip-like protrusions 30 on the signal transmission layer 20, and forming an organic electroluminescent structure 40 which extends from the substrate 15 and the signal transmission layer 20 to a first lateral sides 301 of the strip-like protrusions 30.

The method of the present invention is to be described below in detail.

Firstly, a signal transmission layer 20 is formed on a substrate 15, wherein an electrically-conductive material is formed on the substrate 15, and then a photolithography etching process is performed on the electrically-conductive material to form the pattern of parallel strips. The signal transmission layer 20 having the pattern of parallel strips is used to conduct electrical signals.

Next, the plurality of strip-like protrusions 30 is formed on the signal transmission layer 20. The strip-like protrusions 30 are parallel arranged on the substrate 15, and the axial direction of the strip-like protrusions 30 is vertical to the parallel strips of the signal transmission layer 20. The strip-like protrusion 30 has a first lateral side 301 and a second lateral side 302, which are opposite to each other and along the axial direction of the strip-like protrusion 30. The first included angle created by the first lateral side 301 and the substrate 15 is an obtuse angle, and the second included angle created by the second lateral side 302 and the substrate 15 is an acute angle. According to the material used, the strip-like protrusions 30 are fabricated based on the method shown in FIG. 5A and FIG. 5B or the method shown in FIG. 6A and FIG. 6B. The detailed will no more be repeated herein.

Lastly, an organic electroluminescent structure 40 is formed, and it extends from the substrate 15 and the signal transmission layer 20 to first lateral sides 301 of the strip-like protrusions 30. The organic electroluminescent structure 40 comprises a first electrode layer 401, an organic layer 402 and a second electrode layer 403. The first electrode layer 401 may be fabricated via two methods. One is directly forming the first electrode layer 401 via a thin-film process with a shadow mask having the pattern of parallel strips. The other one is forming an electrically-conductive material and then forming the pattern of parallel strips via a photolithography etching process.

When the organic layer 402 is of an identical material on the first electrode layer 401, it can be directly deposited via an evaporation process. When the organic layer 402 is composed of different organic materials formed on different positions according to luminescence requests of different subpixels, it can be deposited via covering the regions which do not need to be deposited with a shadow mask, and then perform the evaporation process. The second electrode layer 403 can be fabricated via directly depositing an electrically-conductive material on the organic layer 402.

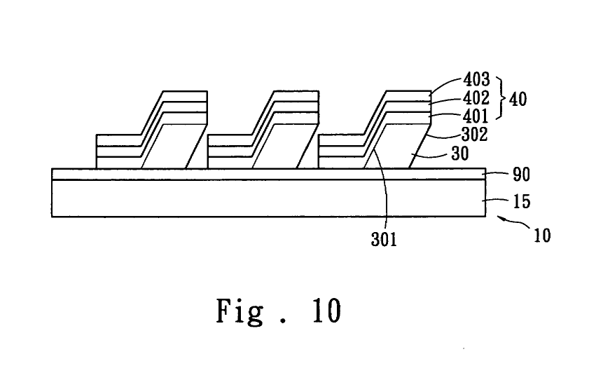

Refer to FIG. 10. The structure of the organic electroluminescent device of the present invention can also be applied to an active matrix OLED. It comprises a substrate 15, a thin-film-transistor (TFT) array 90, strip-like protrusions 30 and an organic electroluminescent structure 40 which are laminated in sequence. The TFT array 90 is disposed on the substrate 15 and functions as a signal transmission layer. The organic electroluminescent structure 40 is electrically connected to the TFT array 90 and is drove by TFT array 90. The TFT array 90 includes at least one TFT and at least one storage capacitor. The strip-like protrusion 30 has a first lateral side 301 and a second lateral side 302, which are opposite to each other and along the axial direction of the strip-like protrusion 30. The first included angle created by the first lateral side 301 and the substrate 15 is an obtuse angle, and the second included angle created by the second lateral side 302 and the substrate 15 is an acute angle.

The organic electroluminescent structure 40 comprises a first electrode layer 401, an organic layer 402 and a second electrode layer 403. The organic electroluminescent structure 40 extends from the substrate 15 and the TFT array 90 to the first lateral sides 301 of the strip-like protrusions 30 and then has disconnections at the undersides of the second lateral sides 302. Herein, the strip-like protrusions 30 can also enlarge the displaying regions and increase the aperture ratio.

As stated above, in the present invention, as the organic electroluminescent structure 40 disconnects at the undersides of the second lateral side 302 of the strip-like protrusions 30 and then has notches there, no spacing gap along that direction is needed to prevent electric connections between different subpixels of the organic electroluminescent structure 40. Thus, each subpixel can omit a spacing gap in one of the axial directions, and the displaying regions are enlarged, and the aperture ratio is increased.

What is claimed is:

1. An organic electroluminescent device, comprising:
a support structure, comprising a substrate, a signal transmission layer disposed on the substrate, a plurality of strip-like protrusions disposed on the surface of the substrate and the signal transmission layer, each of strip-like protrusions having a first lateral side and a second lateral side which are opposite to each other and along the axial direction of the strip-like protrusion, a first included angle created by the first lateral side and the substrate being an obtuse angle, and a second included angle created by the second lateral side and the substrate being an acute angle; and
an organic electroluminescent structure, formed on the signal-transmission-layer-containing side of the support structure, and having disconnections separately disposed at the undersides of the second lateral sides of the strip-like protrusions.

2. The organic electroluminescent device according to claim 1, wherein the strip-like protrusions are made of an organic material, and the first lateral sides and the second lateral sides of the strip-like protrusions are fabricated with an oblique exposure process.

3. The organic electroluminescent device according to claim 1, wherein the strip-like protrusions are made of an inorganic material, and the first lateral sides and the second lateral sides of the strip-like protrusions are fabricated with an oblique etching process.

4. The organic electroluminescent device according to claim 1, wherein the organic electroluminescent structure comprises a first electrode layer, an organic layer and a second electrode layer upward from the substrate sequentially, the first electrode layer of the organic electroluminescent structure having the pattern of parallel strips, the first electrode layer forming a plurality of independent regions via the second lateral sides of the strip-like protrusions and a plurality of subpixel spacing gaps, which are parallel arranged and vertical to the axial direction of the strip-like protrusions.

5. The organic electroluminescent device according to claim 4, wherein the substrate, the first electrode layer, and the strip-like protrusions are made of a transparent material.

6. The organic electroluminescent device according to claim 4, wherein the second electrode layer is made of a transparent material.

7. The organic electroluminescent device according to claim 1, wherein the signal transmission layer has the pattern of parallel strips, and the pattern of parallel strips of the signal transmission layer is vertical to the axial direction of the strip-like protrusions.

8. The organic electroluminescent device according to claim 1, wherein the signal transmission layer is a thin film transistor array.

9. The organic electroluminescent device according to claim 8, wherein the thin film transistor array includes at least one TFT and at least one storage capacitor.

10. A method of fabricating an organic electroluminescent device, comprising the following steps:
forming a signal transmission layer on a substrate;
forming a plurality of strip-like protrusions on the signal transmission layer, wherein each the strip-like protrusion has a first lateral side and a second lateral side which are opposite to each other and along the axial direction of the strip-like protrusion, and a first included angle created by the first lateral side and the substrate is obtuse, and a second included angle created by the second lateral side and the substrate is acute; and
forming an organic electroluminescent structure, which extends from the substrate and the signal transmission layer to the first lateral sides of the strip-like protrusions.

11. The method according to claim 10, wherein the fabrication method of the signal transmission layer is firstly forming an electrically-conductive material on the substrate, and then utilizing a photolithography etching process to form the pattern of parallel strips, which are vertical to the axial direction of the strip-like protrusions.

12. The method according to claim 10, wherein the strip-like protrusions are made of an organic material and fabricated with an oblique exposure process.

13. The method according to claim 10, wherein the strip-like protrusions are made of an inorganic material and fabricated with an oblique etching process.

14. The method according to claim 10, wherein the organic electroluminescent structure further comprises a first electrode layer, an organic layer and a second electrode layer upward from the substrate sequentially.

15. The method according to claim 14, wherein the fabrication method of the first electrode layer is directly forming the first electrode layer via a thin-film process and with a shadow mask having the pattern of parallel strips.

16. The method according to claim 14, wherein the fabrication method of the first electrode layer is firstly forming an electrically-conductive material as the material of the first electrode layer; and then forming the pattern of parallel strips via a photolithography etching process.

17. The method according to claim 14, wherein the organic layer is directly fabricated with an evaporation process.

18. The method according to claim 14, wherein the second electrode layer is fabricated via directly forming an electrically-conductive material on the organic layer.

19. The method according to claim 10, wherein the fabrication method of the signal transmission layer is forming a thin film transistor array on the substrate.

20. The method according to claim 19, wherein the thin film transistor array includes at least one TFT and at least one storage capacitor.
